(19) United States
(12) Patent Application Publication
(10) Pub. No.: US 2026/0136573 A1
(43) Pub. Date: May 14, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Tatsunori SAKANO, Shinagawa Tokyo (JP); Ryohei GEJO, Kawasaki Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/254,185

(22) Filed: Jun. 30, 2025

(30) Foreign Application Priority Data
Nov. 14, 2024 (JP) 2024-199165

(51) Int. Cl. H10D 12/00

(52) U.S. Cl. CPC H10D 12/416; H10D 12/481

(57) ABSTRACT

According to one embodiment, a semiconductor device includes first and second electrodes, a plurality of third electrodes, a fourth electrode, a semiconductor member, first and second insulating members. The first semiconductor portion is between the first electrode portion and the second electrode in a first direction from the first electrode to the second electrode. The second semiconductor portion is between the second electrode portion and the second electrode in the first direction. A direction from the first electrode portion to the second electrode portion crosses the first direction. Each of the first semiconductor portion and the second semiconductor portion of the first electrode includes a first semiconductor region of a first conductivity type, a second semiconductor region of a second conductivity type, and a third semiconductor region of the first conductivity type.

### CROSS-REFERENCE TO RELATED APPLICATIONS

This application is based upon and claims the benefit of priority from Japanese Patent Application No. 2024-199165, filed on Nov. 14, 2024; the entire contents of which are incorporated herein by reference.

### FIELD

Embodiments described herein relate generally to a semiconductor device.

### BACKGROUND

For example, in semiconductor devices, improvements in characteristics are desired.

### BRIEF DESCRIPTION OF THE DRAWINGS

FIG. 1 is a schematic cross-sectional view illustrating a semiconductor device according to a first embodiment;

FIG. 2 is a schematic diagram illustrating the operation of the semiconductor device according to the first embodiment;

FIG. 3 is a schematic cross-sectional view illustrating a semiconductor device according to a second embodiment;

FIG. 4 is a schematic diagram illustrating the operation of the semiconductor device according to the second embodiment; and

FIGS. 5A to 5C are schematic plan views illustrating a semiconductor device according to the embodiment.

### DETAILED DESCRIPTION

According to one embodiment, a semiconductor device includes a first electrode including a first electrode portion and a second electrode portion, a second electrode, a plurality of third electrodes, a fourth electrode, a semiconductor member including a first semiconductor portion and a second semiconductor portion, a first insulating member, and a second insulating member. The first semiconductor portion is between the first electrode portion and the second electrode in a first direction from the first electrode to the second electrode. The second semiconductor portion is between the second electrode portion and the second electrode in the first direction. A direction from the first electrode portion to the second electrode portion crosses the first direction. Each of the first semiconductor portion and the second semiconductor portion includes a first semiconductor region of a first conductivity type, a second semiconductor region of a second conductivity type, and a third semiconductor region of the first conductivity type. The second electrode being electrically connected to the third semiconductor region. The second semiconductor region is between the first semiconductor region and the third semiconductor region. At least a part of the first insulating member is between the plurality of third electrodes and the semiconductor member. The first semiconductor portion includes a fourth semiconductor region of the second conductivity type, and a fifth semiconductor region of the first conductivity type. The fourth electrode is between the first electrode portion and the first semiconductor portion. The fifth semiconductor region is electrically connected to the first electrode portion. The fourth semiconductor region is between the fifth semiconductor region and the first semiconductor region included in the first semiconductor portion. The second insulating member is between the fourth electrode and the first semiconductor portion. The second semiconductor portion includes a sixth semiconductor region of the second conductivity type, and a seventh semiconductor region of the first conductivity type. The sixth semiconductor region and the seventh semiconductor region are between the second electrode portion and the first semiconductor region included in the second semiconductor portion.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

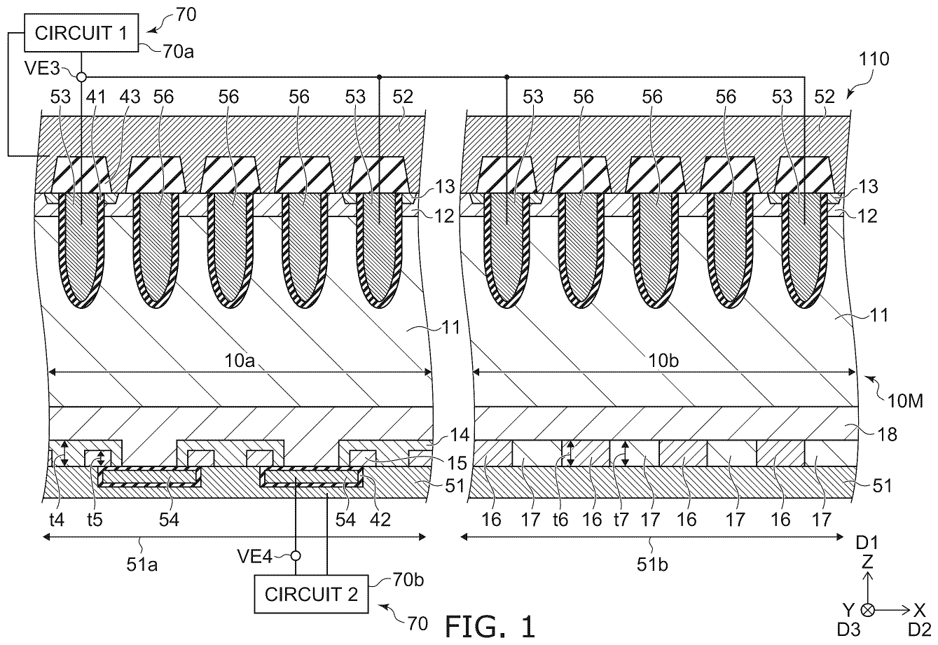

FIG. 1 is a schematic cross-sectional view illustrating a semiconductor device according to the first embodiment.

As shown in FIG. 1, a semiconductor device 110 according to the embodiment includes a first electrode 51, a second electrode 52, a plurality of third electrodes 53, a fourth electrode 54, a semiconductor member 10M, a first insulating member 41, and a second insulating member 42.

The first electrode 51 includes a first electrode portion 51a and a second electrode portion 51b. The semiconductor member 10M includes a first semiconductor portion 10a and a second semiconductor portion 10b. The first semiconductor portion 10a is provided between the first electrode portion 51a and the second electrode 52 in a first direction D1 from the first electrode 51 to the second electrode 52. The second semiconductor portion 10b is provided between the second electrode portion 51b and the second electrode 52 in the first direction D1.

The first direction D1 is defined as a Z-axis direction. A direction perpendicular to the Z-axis direction is defined as an X-axis direction. A direction perpendicular to the Z-axis direction and the X-axis direction is defined as a Y-axis direction.

For example, the first electrode 51 and the second electrode 52 are along the X-Y plane. The semiconductor member 10M is along the X-Y plane.

A direction from the first electrode portion 51a to the second electrode portion 51b crosses the first direction D1. A direction from the first semiconductor portion 10a to the second semiconductor portion 10b crosses the first direction D1.

Each of the first semiconductor portion 10a and the second semiconductor portion 10b includes a first semiconductor region 11 of a first conductivity type, a second semiconductor region 12 of a second conductivity type, and a third semiconductor region 13 of the first conductivity type.

The first conductivity type is one of n-type and p-type. The second conductivity type is the other of n-type and p-type. In the following, the first conductivity type is n-type, and the second conductivity type is p-type.

The second electrode 52 is electrically connected to the third semiconductor region 13. The second semiconductor region 12 is provided between the first semiconductor region 11 and the third semiconductor region 13. The first semiconductor region 11 may function, for example, as a drift layer. The second semiconductor region 12 may function, for example, as a base layer. The third semiconductor region 13 may function, for example, as a source layer.

At least a part of the first insulating member 41 is provided between the plurality of third electrodes 53 and the semiconductor member 10M. The first insulating member 41 insulates the plurality of third electrodes 53 from the semiconductor member 10M.

The first semiconductor portion 10a includes a fourth semiconductor region 14 of the second conductivity type and a fifth semiconductor region 15 of the first conductivity type. The fourth electrode 54 is provided between the first electrode portion 51a and the first semiconductor portion 10a. The fifth semiconductor region 15 is electrically connected to the first electrode 51 (for example, the first electrode portion 51a). The fourth semiconductor region 14 is provided between the fifth semiconductor region 15 and the first semiconductor region 11 included in the first semiconductor portion 10a.

The second insulating member 42 is provided between the fourth electrode 54 and the first semiconductor portion 10a. A part of the second insulating member 42 may be provided between the fourth electrode 54 and the first electrode 51. The second insulating member 42 insulates the fourth electrode 54 from the semiconductor member 10M (the first semiconductor portion 10a). The second insulating member 42 insulates the fourth electrode 54 from the first electrode 51.

The second semiconductor portion 10b includes a sixth semiconductor region 16 of the second conductivity type and a seventh semiconductor region 17 of the first conductivity type. The sixth semiconductor region 16 and the seventh semiconductor region 17 are located between the second electrode portion 51b and the first semiconductor region 11 included in the second semiconductor portion 10b.

In the semiconductor device 110, current flowing between the first electrode 51 and the second electrode 52 is controlled by a potential of the plurality of third electrodes 53. The potential of the plurality of third electrodes 53 may be, for example, a potential based on a potential of the second electrode 52. The first electrode 51 functions, for example, as a collector electrode. The second electrode 52 functions, for example, as an emitter electrode. The plurality of third electrodes 53 function as gate electrodes (for example, main gate electrodes). The semiconductor device 110 is, for example, an IGBT (Insulated Gate Bipolar Transistor).

In the semiconductor device 110, a fourth electrode 54 is provided. By controlling a potential of the fourth electrode 54, the flow of carriers between the semiconductor member 10M and the first electrode 51 can be controlled. The fourth electrode 54 functions, for example, as a back gate.

The first electrode portion 51a and the first semiconductor portion 10a are regions where the back gate is provided. The second electrode portion 51b and the second semiconductor portion 10b are regions where the back gate is not provided. The second semiconductor portion 10b is a region where the sixth semiconductor region 16 of p-type and the seventh semiconductor region 17 of n-type are provided. The second electrode portion 51b and the second semiconductor portion 10b correspond to an RC-IGBT (Reverse Conductive Insulated Gate Bipolar Transistor) region.

In the embodiment, the back gate region and the RC-IGBT region are provided in one continuous semiconductor member 10M. Thereby, it becomes possible to provide a semiconductor device with improved characteristics.

For example, in an RC-IGBT, a first reference example is considered in which a p-type semiconductor region is provided with a large area on the side of the first electrode 51 (back side) in order to suppress snapback. The large area p-type semiconductor region functions as a trigger region that suppresses snapback.

In such a first reference example, there is no path for electrons to escape in the large area p-type semiconductor region. As a result, for example, a tail current is generated. Furthermore, in the first reference example, when the diode mode state should be entered, the diode current does not flow. This deteriorates the diode characteristics.

In contrast, in the embodiment, the accumulated electrons can be discharged via the channel of the back gate. Thereby, it becomes possible to suppress the tail current. Furthermore, the diode current can flow via the channel of the back gate. Thereby, it becomes possible to obtain good diode characteristics. According to the embodiment, the tail current can be suppressed while the snapback is suppressed, and good diode characteristics can be obtained. According to the embodiment, the characteristics can be improved.

Furthermore, in a second reference example, a control gate electrode is provided in addition to the large area p-type semiconductor region in the first reference example. In the second reference example, the diode current does not flow due to the large area p-type semiconductor region, and therefore the function of the control gate electrode cannot be obtained.

In contrast, in the embodiment, the back gate allows the diode current to flow, and therefore the effect of the control gate electrode operation (e.g., suppression of losses) can be obtained.

On the other hand, there is a third reference example in which the RC-IGBT portion (second electrode portion 51b) is not provided, and the back gate is provided over the entire surface. In the third reference example, in order to operate the back gate appropriately, restrictions are likely to be generated on the area ratio between the p-type semiconductor region and the n-type semiconductor region on the back side. This generates a limit on the improvement of characteristics.

In contrast, in the embodiment, both the RC-IGBT portion and the back gate portion are provided. This relaxes the restrictions on the area ratio. This allows for higher performance to be obtained.

In the embodiment, the direction from the sixth semiconductor region 16 to the seventh semiconductor region 17 crosses the first direction D1.

The second semiconductor portion 10b may include a plurality of sixth semiconductor regions 16 and a plurality of seventh semiconductor regions 17. One of the plurality of sixth semiconductor regions 16 is located between one of the plurality of seventh semiconductor regions 17 and another one of the plurality of seventh semiconductor regions 17. One of the plurality of seventh semiconductor regions 17 is located between one of the plurality of sixth semiconductor regions 16 and another one of the plurality of sixth semiconductor regions 16.

The sixth semiconductor regions 16 and the seventh semiconductor regions 17 may be arranged alternately in a direction crossing the first direction D1.

As shown in FIG. 1, each of the first semiconductor portion 10a and the second semiconductor portion 10b may further include an eighth semiconductor region 18 of the first conductivity type. The fourth semiconductor region 14 is located between the first electrode portion 51a and a part of the eighth semiconductor region 18. The sixth semiconductor region 16 and the seventh semiconductor region 17 are located between the second electrode portion 51b and another part of the eighth semiconductor region 18.

An eighth impurity concentration of the first conductivity type in the eighth semiconductor region 18 is higher than a first impurity concentration of the first conductivity type in the first semiconductor region 11. The eighth impurity concentration may be, for example, not less than 1×10¹⁸ cm⁻³ and not more than 1×10²¹ cm⁻³. The first impurity concentration may be, for example, not less than 1×10¹² cm⁻³ and not more than 1×10¹⁵ cm⁻³.

As shown in FIG. 1, the direction from a part of the fourth electrode 54 to a part of the eighth semiconductor region 18 may be along the first direction D1. A part of the fourth semiconductor region 14 is located between a part of the eighth semiconductor region 18 and the fifth semiconductor region 15 in a direction crossing the first direction D1.

In the example of FIG. 1, the plurality of third electrodes 53 are arranged along a second direction D2 crossing the first direction D1. For example, the third electrodes 53 extend along a third direction D3. The third direction D3 crosses a plane including the first direction D1 and the second direction D2. The fourth electrode 54 extends along the third direction D3.

As shown in FIG. 1, a plurality of fourth electrodes 54 may be provided. A direction from one of the fourth electrodes 54 to another one of the fourth electrodes 54 may be along the second direction D2. The direction in which the plurality of fourth electrodes 54 are arranged may be along the direction in which the plurality of third electrodes 53 are arranged. Thereby, the current path controlled by the third electrodes 53 becomes aligned along the current path controlled by the fourth electrodes 54. The current can be effectively controlled. In the embodiment, the direction in which the plurality of fourth electrodes 54 extend may cross the direction in which the plurality of third electrodes 53 extend.

In the embodiment, the pitch of the plurality of sixth semiconductor regions 16 (sixth semiconductor region pitch) is preferably, for example, not less than 3 times and not more than 2000 times the pitch of the plurality of third electrodes 53 (third electrode pitch). There by, it becomes possible to improve the efficiency of electron injection from the back surface in the diode operation by, for example, reducing the back surface gate pitch. For example, it is possible to improve the diode current efficiency of the entire chip. In one example, the sixth semiconductor region pitch is, for example, not less than 100 μm and not more than 1000 μm. The third electrode pitch is, for example, not less than 0.5 μm and not more than 30 μm.

The pitch of the plurality of fourth electrodes 54 (fourth electrode pitch) is preferably, for example, not less than 1 time and not more than 2000 times the pitch of the plurality of third electrodes 53 (third electrode pitch). The fourth electrode pitch may be larger than the third electrode pitch. In one example, the fourth electrode pitch is, for example, not less than 0.5 μm and not more than 1000 μm.

The pitch of the plurality of fourth electrodes 54 (fourth electrode pitch) is preferably not less than 0.0005 times and not more than 10 times the pitch of the plurality of sixth semiconductor regions 16 (sixth semiconductor region pitch). The fourth electrode pitch may be less than the sixth semiconductor region pitch.

A fourth impurity concentration of the second conductivity type in the fourth semiconductor region 14 is preferably not less than 0.1 times and not more than 1000 times a sixth impurity concentration of the second conductivity type in the sixth semiconductor region 16. Thereby, it becomes easier, for example, to effectively pass an IGBT current through the entire chip. For example, the fourth impurity concentration may be higher than the sixth impurity concentration.

A fifth impurity concentration of the first conductivity type in the fifth semiconductor region 15 is preferably not less than 0.001 times and not more than 10 times a seventh impurity concentration of the first conductivity type in the seventh semiconductor region 17. Thereby, it becomes easier to effectively pass the diode current, for example. For example, the fifth impurity concentration may be lower than the seventh impurity concentration.

As shown in FIG. 1, a thickness of the fourth semiconductor region 14 along the first direction D1 is defined as a fourth thickness t4. A thickness of the sixth semiconductor region 16 along the first direction D1 is defined as a sixth thickness t6. In one example, the fourth thickness t4 is not less than 10 nm and not more than 100 μm. In one example, the sixth thickness t6 is not less than 1 nm and not more than 100 μm.

A thickness of the fifth semiconductor region 15 along the first direction D1 is defined as a fifth thickness t5. A thickness of the seventh semiconductor region 17 along the first direction D1 is defined as a seventh thickness t7. In one example, the fifth thickness t5 is not less than 1 nm and not more than 100 μm. In one example, the seventh thickness t7 is not less than 1 nm and not more than 100 μm.

As shown in FIG. 1, the direction from the third electrode 53 to the second semiconductor region 12 crosses the first direction D1. The direction from the third electrode 53 to the third semiconductor region 13 crosses the first direction D1. The third electrode 53 is a trench-type gate electrode. In the embodiment, a planar-type gate electrode structure may be applied.

As shown in FIG. 1, in this example, the semiconductor device 110 further includes a sixth electrode 56. The sixth electrode 56 is provided between one of the plurality of third electrodes 53 and another one of the plurality of third electrodes 53. part of the first insulating member 41 contacts a part of the plurality of third electrodes 53 and the third semiconductor region 13. The first insulating member 41 does not contact the third semiconductor region 13 between the sixth electrode 56 and the third semiconductor region 13.

The semiconductor device 110 may further include a third insulating member 43. The third insulating member 43 is provided between the plurality of third electrodes 53 and the second electrode 52. The third insulating member 43 is provided between the sixth electrode 56 and the second electrode 52.

As shown in FIG. 1, a controller 70 may be provided. The controller 70 may be included in the semiconductor device 110. The controller 70 may be provided separately from the semiconductor device 110. The controller 70 is electrically connected to the first electrode 51, the second electrode 52, the third electrode 53, and the fourth electrode 54. The controller 70 is configured to control a potential of the plurality of third electrodes 53 (third electrode potential VE3). The controller 70 is configured to control a potential of the fourth electrode 54 (fourth electrode potential VE4). The third electrode potential VE3 may be potentials based on a potential of the second electrode 52, for example.

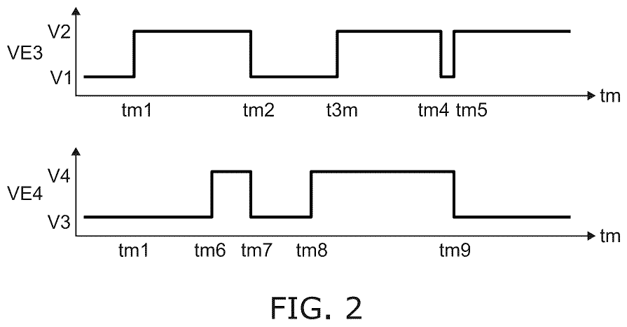

FIG. 2 is a schematic diagram illustrating the operation of the semiconductor device according to the first embodiment.

The horizontal axis of FIG. 2 is time tm. The vertical axis of FIG. 2 is the third electrode potential VE3 or the fourth electrode potential VE4.

The controller 70 is configured to cause the third electrodes 53 to change from a first potential V1 to a second potential V2 higher than the first potential V1 at a first time tm1. The controller 70 is configured to cause the third electrodes 53 to change from the second potential V2 to the first potential V1 at a second time tm2 after the first time tm1. The controller 70 is configured to cause the third electrodes 53 to change from the first potential V1 to the second potential V2 at a third time tm3 after the second time tm2. The controller 70 is configured to cause the third electrodes 53 to change from the second potential V2 to the first potential V1 at a fourth time tm4 after the third time tm3. The controller 70 is configured to cause the third electrodes 53 to cause from the second potential V2 to the first potential V1 at a fifth time tm5 after the fourth time tm4. The first potential V1 and the second potential V2 are potentials based on the potential of the second electrode 52 as a reference.

The controller 70 is configured to set the fourth electrode 54 to a third potential V3 at the first time tm1. The controller 70 is configured to cause the fourth electrode 54 to change from the third potential V3 to a fourth potential V4 higher than the third potential V3 at a sixth time tm6 between the first time tm1 and the second time tm2. The controller 70 is configured to cause the fourth electrode 54 to change from the fourth potential V4 to the third potential V3 at a seventh time tm7 between the sixth time tm6 and the third time tm3. The controller 70 is configured to cause the fourth electrode 54 to change from the third potential V3 to the fourth potential V4 at an eighth time tm8 between the seventh time tm7 and the third time tm3. The controller 70 is configured to cause the fourth electrode 54 to change from the third potential V3 to the fourth potential V4 at the eighth time tm8 between the seventh time tm7 and the third time tm3. The controller 70 is configured to cause the fourth electrode 54 to change from the fourth potential V4 to the third potential V3 at a ninth time tm9 after the fourth time tm4. The third potential V3 and the fourth potential V4 are potentials based on the potential of the first electrode 51 as a reference.

The seventh time tm7 may be substantially the same as the second time tm2. The ninth time tm9 may be substantially the same as the fifth time tm5.

The period between the first time tm1 and the second time tm2 corresponds to, for example, the IGBT mode period. The period between the eighth time tm8 and the fourth time tm4 corresponds to the diode mode period. The period between the third time tm3 and the fourth time tm4 corresponds to the DESAT control period. In the DESAT control period, carriers are extracted by control of the front face gate.

In the period between the sixth time tm6 and the seventh time tm7, carriers are discharged by the operation of the fourth electrode 54 (back gate). The period between the eighth time tm8 and the ninth time tm9 corresponds to the on-period of the back gate in the diode mode.

As shown in FIG. 2, the controller 70 may include a first circuit 70a and a second circuit 70b. The first circuit 70a is configured to control the potential of the plurality of third electrodes 53 (third electrode potential VE3). The second circuit 70b is configured to control the potential of the fourth electrode 54 (fourth electrode potential VE4). These circuits may be insulated from each other. The insulation may be performed, for example, by a photocoupler or a DC-DC converter.

### Second Embodiment

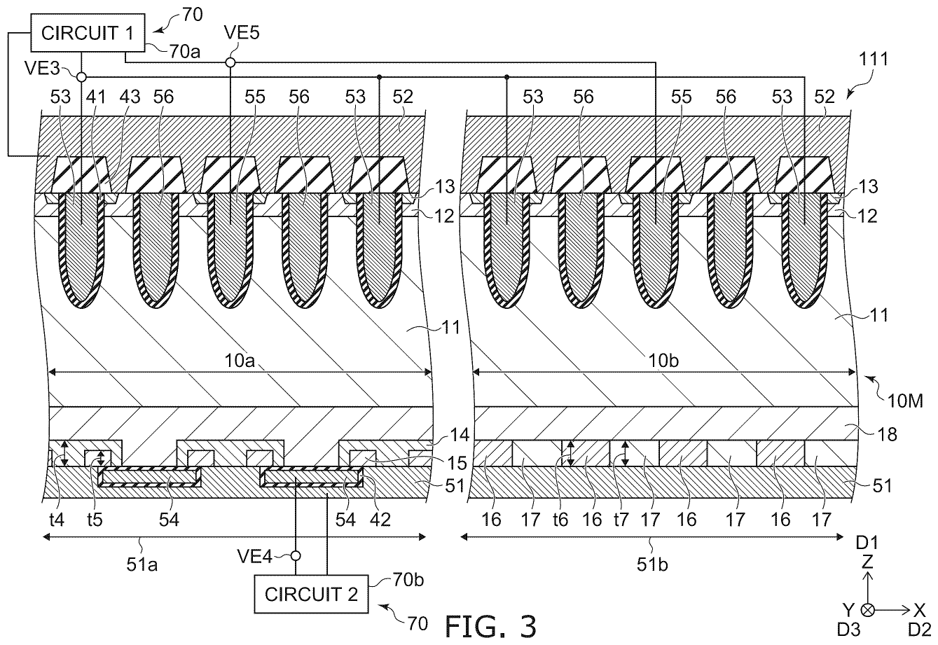

FIG. 3 is a schematic cross-sectional view illustrating a semiconductor device according to a second embodiment.

As shown in FIG. 3, a semiconductor device 111 according to the embodiment further includes a fifth electrode 55. Except for this, the configuration of the semiconductor device 111 may be the same as the configuration of the semiconductor device 110.

In the semiconductor device 111, the fifth electrode 55 is provided between one of the plurality of third electrodes 53 and another one of the plurality of third electrodes 53. A part of the first insulating member 41 is provided between the fifth electrode 55 and the semiconductor member 10M. The part of the first insulating member 41 insulates the fifth electrode 55 from the semiconductor member 10M.

The fifth electrode 55 functions as, for example, a control gate. The fifth electrode 55 may be driven separately from the third electrode 53.

The semiconductor device 111 may be provided with the controller 70. The controller 70 may be configured to further control a fifth electrode potential VE5 of the fifth electrode 55 in addition to the operation described with reference to FIG. 2. For example, the first circuit 70a is configured to control the fifth electrode potential VE5.

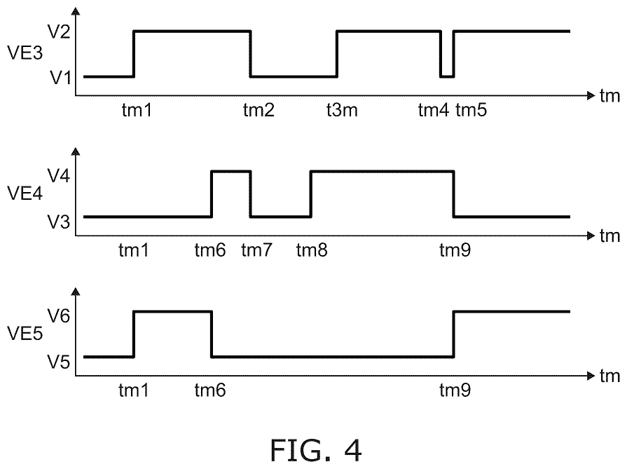

FIG. 4 is a schematic diagram illustrating the operation of the semiconductor device according to the second embodiment.

The horizontal axis of FIG. 4 is time tm. The vertical axis of FIG. 4 is the third electrode potential VE3, the fourth electrode potential VE4, or the fifth electrode potential VE5.

As shown in FIG. 4, the controller 70 is configured to perform the following operations in addition to the operations described with reference to FIG. 2. The controller 70 is configured to cause the fifth electrode 55 to change from the fifth potential V5 to a sixth potential V6 higher than the fifth potential V5 at a first time tm1. The controller 70 is configured to cause the fifth electrode 55 to change from the sixth potential V6 to the fifth potential V5 at a sixth time tm6. The controller 70 is configured to cause the fifth electrode 55 to change from the fifth potential V5 to the sixth potential V6 at a ninth time tm9. For example, the controller 70 is configured to keep the fifth electrode 55 at the fifth potential V5 between the sixth time tm6 and the ninth time tm9.

For example, the transition of the fifth electrode 55 from the sixth potential V6 to the fifth potential V5 at the sixth time tm6 causes carriers to be discharged in the vicinity of the fifth electrode 55.

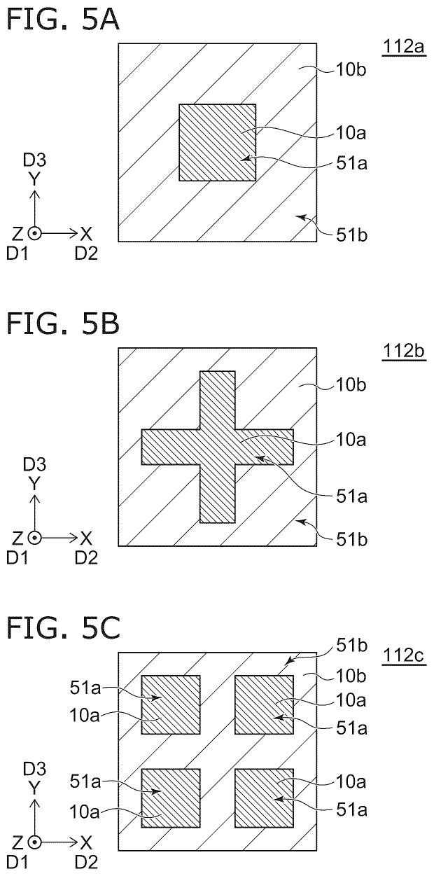

FIGS. 5A to 5C are schematic plan views illustrating a semiconductor device according to the embodiment.

These figures illustrate planar patterns of the first electrode portion 51a and the second electrode portion 51b. These figures illustrate the planar patterns of the first semiconductor portion 10a and the second semiconductor portion 10b.

As shown in FIGS. 5A and 5B, the first electrode portion 51a may be provided between a part of the second electrode portion 51b and another part of the second electrode portion 51b in a direction crossing the first direction D1. The first semiconductor portion 10a may be provided between a part of the second semiconductor portion 10b and another part of the second semiconductor portion 10b in a direction crossing the first direction D1. The planar patterns of the first electrode portion 51a and the first semiconductor portion 10a are arbitrary.

As shown in FIG. 5C, a plurality of first electrode portions 51a may be provided. One of the plurality of first electrode portions 51a may be provided between a part of the second electrode portion 51b and another part of the second electrode portion 51b. A plurality of first semiconductor portions 10a may be provided. One of the plurality of first semiconductor portions 10a may be provided between a part of the second semiconductor portion 10b and another part of the second semiconductor portion 10b.

In the embodiment, at least one of the first electrode 51 or the second electrode 52 may include a metal. The metal may include at least one selected from the group consisting of Al, Ti, Ni, Au, Ag, and Cu. At least one of the third electrode 53, the fourth electrode 54, the fifth electrode 55, or the sixth electrode 56 may include polysilicon. The semiconductor member 10M may include silicon. The semiconductor member 10M may include a compound semiconductor. The compound semiconductor may include at least one selected from the group consisting of SiC, GaN, GaO, and GaAs.

In the embodiment, information on the shape of the semiconductor region is obtained, for example, from an electron microscope image. Information on the composition and element concentration is obtained, for example, from EDX (Energy Dispersive X-ray Spectroscopy) or SIMS (Secondary Ion Mass Spectrometry).

The embodiment may include the following Technical proposals.

### Technical Proposal 1)

A semiconductor device, comprising:
a first electrode including a first electrode portion and a second electrode portion;
a second electrode;
a plurality of third electrodes;
a fourth electrode;
a semiconductor member including a first semiconductor portion and a second semiconductor portion;
a first insulating member; and
a second insulating member,
the first semiconductor portion being between the first electrode portion and the second electrode in a first direction from the first electrode to the second electrode,
the second semiconductor portion being between the second electrode portion and the second electrode in the first direction,
a direction from the first electrode portion to the second electrode portion crossing the first direction,
each of the first semiconductor portion and the second semiconductor portion including
   a first semiconductor region of a first conductivity type,
   a second semiconductor region of a second conductivity type, and
   a third semiconductor region of the first conductivity type,
the second electrode being electrically connected to the third semiconductor region,
the second semiconductor region being between the first semiconductor region and the third semiconductor region,
at least a part of the first insulating member being between the plurality of third electrodes and the semiconductor member,
the first semiconductor portion including
   a fourth semiconductor region of the second conductivity type, and
   a fifth semiconductor region of the first conductivity type,
the fourth electrode being between the first electrode portion and the first semiconductor portion,
the fifth semiconductor region being electrically connected to the first electrode portion,
the fourth semiconductor region being between the fifth semiconductor region and the first semiconductor region included in the first semiconductor portion,
the second insulating member being between the fourth electrode and the first semiconductor portion,
the second semiconductor portion including
   a sixth semiconductor region of the second conductivity type, and
   a seventh semiconductor region of the first conductivity type,
the sixth semiconductor region and the seventh semiconductor region being between the second electrode portion and the first semiconductor region included in the second semiconductor portion.

### Technical Proposal 2

The semiconductor device according to Technical proposal 1, wherein
a direction from the sixth semiconductor region to the seventh semiconductor region crosses the first direction.

### Technical Proposal 3

The semiconductor device according to Technical proposal 2, wherein
the second semiconductor portion includes a plurality of the sixth semiconductor regions and a plurality of the seventh semiconductor regions,
one of the plurality of the sixth semiconductor regions is between one of the plurality of the seventh semiconductor regions and another one of the plurality of the seventh semiconductor regions, and
the one of the plurality of the seventh semiconductor regions is between the one of the plurality of the sixth semiconductor regions and another one of the plurality of the sixth semiconductor regions.

### Technical Proposal 4

The semiconductor device according to any one of Technical proposals 1 to 3, wherein
a sixth semiconductor region pitch of the plurality of sixth semiconductor regions is not less than 3 times and not more than 2000 times a third electrode pitch of the plurality of third electrodes.

### Technical Proposal 5

The semiconductor device according to any one of Technical proposals 1 to 3, wherein
the plurality of third electrodes are arranged along a second direction crossing the first direction,
the plurality of third electrodes extend along a third direction crossing a plane including the first direction and the second direction, and
the fourth electrode extends along the third direction.

### Technical Proposal 6

The semiconductor device according to Technical proposal 1 or 2, wherein
a plurality of the fourth electrodes are provided, and
a fourth electrode pitch of the plurality of the fourth electrodes is not less than 1 time and not more than 2000 times a third electrode pitch of the plurality of the third electrodes.

### Technical Proposal 7

The semiconductor device according to Technical proposal 3, wherein
a plurality of the fourth electrodes are provided, and
a fourth electrode pitch of the plurality of the fourth electrodes is not less than 0.0005 times and not more than 10 times a sixth semiconductor region pitch of the plurality of the sixth semiconductor regions.

### Technical Proposal 8

The semiconductor device according to any one of Technical proposals 1 to 7, wherein
a fourth impurity concentration of the second conductivity type in the fourth semiconductor region is not less than 0.1 times and not more than 1000 times a sixth impurity concentration of the second conductivity type in the sixth semiconductor region.

### Technical Proposal 9

The semiconductor device according to any one of Technical proposals 1 to 8, wherein
a fifth impurity concentration of the first conductivity type in the fifth semiconductor region is not less than 0.001 times and not more than 10 times a seventh impurity concentration of the first conductivity type in the seventh semiconductor region.

### Technical Proposal 10

The semiconductor device according to any one of Technical proposals 1 to 9, wherein
the sixth semiconductor region and the seventh semiconductor region are arranged alternately in a direction crossing the first direction.

### Technical Proposal 11

The semiconductor device according to any one of Technical proposals 1 to 3, wherein
a direction in which the fourth electrode extends crosses a direction in which the plurality of third electrodes extend.

### Technical Proposal 12

The semiconductor device according to any one of Technical proposals 1 to 11, wherein
each of the first semiconductor portion and the second semiconductor portion further includes an eighth semiconductor region of the first conductivity type,
the fourth semiconductor region is between the first electrode portion and a part of the eighth semiconductor region, and
the sixth semiconductor region and the seventh semiconductor region are between the second electrode portion and another part of the eighth semiconductor region.

### Technical Proposal 13

The semiconductor device according to any one of Technical proposals 1 to 12, further comprising:
a sixth electrode,
the sixth electrode being between one of the plurality of third electrodes and another one of the plurality of third electrodes,
a part of the first insulating member contacting a part of the plurality of third electrodes and the third semiconductor region, and
the first insulating member not contacting the third semiconductor region between the sixth electrode and the third semiconductor region.
(Technical proposal 14

The semiconductor device according to any one of Technical proposal 1-13, further comprising:
a controller,
the controller being configured to cause the plurality of third electrodes to change from a first potential to a second potential higher than the first potential at a first time,
the controller being configured to cause the plurality of third electrodes to change from the second potential to the first potential at a second time after the first time,
the controller being configured to cause the plurality of third electrodes to change from the first potential to the second potential at a third time after the second time,
the controller being configured to cause the plurality of third electrodes to change from the first potential to the second potential at a fourth time after the third time,
the controller being configured to cause the plurality of third electrodes to change from the second potential to the first potential at a fourth time after the third time,
the controller being configured to cause the plurality of third electrodes to change from the first potential to the first potential at a fifth time after the fourth time,
the controller being configured to set the fourth electrode to a third potential at the first time,
the controller being configured to cause the fourth electrode to change from the third potential to a fourth potential higher than the third potential at a sixth time between the first time and the second time,
the controller being configured to cause the fourth electrode to change from the fourth potential to the third potential at a seventh time between the sixth time and the third time,
the controller being configured to cause the fourth electrode to change from the fourth potential to the third potential at an eighth time between the seventh time and the third time,
the controller being configured to cause the fourth electrode to change from the third potential to the fourth potential at an eighth time between the seventh time and the third time,
the controller being configured to cause the fourth electrode to change from the third potential to the fourth potential at a ninth time after the fourth time,.
(Technical proposal 15
The semiconductor device according to any one of Technical proposals 1 to 12, further comprising:
a fifth electrode,
the fifth electrode being between one of the plurality of third electrodes and another one of the plurality of third electrodes, and
a part of the first insulating member being provided between the fifth electrode and the semiconductor member.
(Technical proposal 16

The semiconductor device according to Technical Proposal 15, further comprising:
a controller,
the controller being configured to cause the plurality of third electrodes to change from a first potential to a second potential higher than the first potential at a first time,
the controller being configured to cause the plurality of third electrodes to change from the second potential to the first potential at a second time after the first time,
the controller being configured to cause the plurality of third electrodes to change from the first potential to the second potential at a third time after the second time,
the controller being configured to cause the plurality of third electrodes to change from the first potential to the second potential at a fourth time after the third time,
the controller being configured to cause the plurality of third electrodes to change from the second potential to the first potential at a fifth time after the fourth time,
the controller being configured to cause the plurality of third electrodes to change from the first potential to the second potential at a fifth time after the fourth time,
the controller being configured to set the fourth electrodes to a third potential at the first time,
the controller being configured to cause the fourth electrodes to change from the third potential to a fourth potential higher than the third potential at a sixth time between the first time and the second time,
the controller being configured to cause the fourth electrode to change from the fourth potential to the third potential at a seventh time between the sixth time and the third time,
the controller being configured to cause the fourth electrode to change from the third potential to the fourth potential at an eighth time between the seventh time and the third time,
the controller being configured to cause the fourth electrode to change from the fourth potential to the third potential at a ninth time after the fourth time,
the controller being configured to cause the fifth electrode to change from the fifth potential to a sixth potential higher than the fifth potential at the first time,
the controller being configured to cause the fifth electrode to change from the sixth potential to the fifth potential at the sixth time,
the controller being configured to cause the fifth electrode from the fifth potential to the sixth potential at the ninth time.
(Technical proposal 17

### The Semiconductor Device According to Technical Proposal 16, wherein

the controller is configured to keep the fifth electrode at the fifth potential between the sixth time and the ninth time.

### Technical Proposal 18

The semiconductor device according to any one of Technical proposals 1 to 17, wherein
the first electrode portion is provided between a part of the second electrode portion and another part of the second electrode portion in a direction crossing the first direction.

### Technical Proposal 19

The semiconductor device according to any one of Technical proposals 1 to 18, wherein
the first semiconductor portion is provided between a part of the second semiconductor portion and another part of the second semiconductor portion in a direction crossing the first direction.

### Technical Proposal 20

The semiconductor device according to any one of Technical proposals 1 to 17, wherein
a plurality of the first electrode portions are provided, and
one of the plurality of the first electrode portions is between a part of the second electrode portion and another part of the second electrode portion.

According to the embodiment, a semiconductor device is provided that can improve characteristics.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, semiconductor regions, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode including a first electrode portion and a second electrode portion;
a second electrode;
a plurality of third electrodes;
a fourth electrode;
a semiconductor member including a first semiconductor portion and a second semiconductor portion;
a first insulating member; and
a second insulating member,
the first semiconductor portion being between the first electrode portion and the second electrode in a first direction from the first electrode to the second electrode,
the second semiconductor portion being between the second electrode portion and the second electrode in the first direction,
a direction from the first electrode portion to the second electrode portion crossing the first direction,
each of the first semiconductor portion and the second semiconductor portion including
a first semiconductor region of a first conductivity type,
a second semiconductor region of a second conductivity type, and
a third semiconductor region of the first conductivity type,
the second electrode being electrically connected to the third semiconductor region,
the second semiconductor region being between the first semiconductor region and the third semiconductor region,
at least a part of the first insulating member being between the plurality of third electrodes and the semiconductor member,
the first semiconductor portion including
a fourth semiconductor region of the second conductivity type, and
a fifth semiconductor region of the first conductivity type,
the fourth electrode being between the first electrode portion and the first semiconductor portion,
the fifth semiconductor region being electrically connected to the first electrode portion,
the fourth semiconductor region being between the fifth semiconductor region and the first semiconductor region included in the first semiconductor portion,
the second insulating member being between the fourth electrode and the first semiconductor portion,
the second semiconductor portion including
a sixth semiconductor region of the second conductivity type, and
a seventh semiconductor region of the first conductivity type,
the sixth semiconductor region and the seventh semiconductor region being between the second electrode portion and the first semiconductor region included in the second semiconductor portion.

2. The semiconductor device according to claim 1, wherein
a direction from the sixth semiconductor region to the seventh semiconductor region crosses the first direction.

3. The semiconductor device according to claim 2, wherein
the second semiconductor portion includes a plurality of the sixth semiconductor regions and a plurality of the seventh semiconductor regions,
one of the plurality of the sixth semiconductor regions is between one of the plurality of the seventh semiconductor regions and another one of the plurality of the seventh semiconductor regions, and
the one of the plurality of the seventh semiconductor regions is between the one of the plurality of the sixth semiconductor regions and another one of the plurality of the sixth semiconductor regions.

4. The semiconductor device according to claim 1, wherein
a sixth semiconductor region pitch of the plurality of sixth semiconductor regions is not less than 3 times and not more than 2000 times a third electrode pitch of the plurality of third electrodes.

5. The semiconductor device according to claim 1, wherein
the plurality of third electrodes are arranged along a second direction crossing the first direction,
the plurality of third electrodes extend along a third direction crossing a plane including the first direction and the second direction, and
the fourth electrode extends along the third direction.

6. The semiconductor device according to claim 1, wherein
a plurality of the fourth electrodes are provided, and
a fourth electrode pitch of the plurality of the fourth electrodes is not less than 1 time and not more than 2000 times a third electrode pitch of the plurality of the third electrodes.

7. The semiconductor device according to claim 1, wherein
a plurality of the fourth electrodes are provided, and
a fourth electrode pitch of the plurality of the fourth electrodes is not less than 0.0005 times and not more than 10 times a sixth semiconductor region pitch of the plurality of the sixth semiconductor regions.

8. The semiconductor device according to claim 1, wherein
a fourth impurity concentration of the second conductivity type in the fourth semiconductor region is not less than 0.1 times and not more than 1000 times a sixth impurity concentration of the second conductivity type in the sixth semiconductor region.

9. The semiconductor device according to claim 1, wherein
a fifth impurity concentration of the first conductivity type in the fifth semiconductor region is not less than 0.001 times and not more than 10 times a seventh impurity concentration of the first conductivity type in the seventh semiconductor region.

10. The semiconductor device according to claim 1, wherein
the sixth semiconductor region and the seventh semiconductor region are arranged alternately in a direction crossing the first direction.

11. The semiconductor device according to claim 1, wherein
a direction in which the fourth electrode extends crosses a direction in which the plurality of third electrodes extend.

12. The semiconductor device according to claim 1, wherein
each of the first semiconductor portion and the second semiconductor portion further includes an eighth semiconductor region of the first conductivity type,
the fourth semiconductor region is between the first electrode portion and a part of the eighth semiconductor region, and
the sixth semiconductor region and the seventh semiconductor region are between the second electrode portion and another part of the eighth semiconductor region.

13. The semiconductor device according to claim 1, further comprising:
a sixth electrode,
the sixth electrode being between one of the plurality of third electrodes and another one of the plurality of third electrodes,
a part of the first insulating member contacting a part of the plurality of third electrodes and the third semiconductor region, and
the first insulating member not contacting the third semiconductor region between the sixth electrode and the third semiconductor region.

14. The semiconductor device according to claim 1, further comprising:
a controller,
the controller being configured to cause the plurality of third electrodes to change from a first potential to a second potential higher than the first potential at a first time,
the controller being configured to cause the plurality of third electrodes to change from the second potential to the first potential at a second time after the first time,
the controller being configured to cause the plurality of third electrodes to change from the first potential to the second potential at a third time after the second time,
the controller being configured to cause the plurality of third electrodes to change from the first potential to the second potential at a fourth time after the third time,
the controller being configured to cause the plurality of third electrodes to change from the second potential to the first potential at a fourth time after the third time,
the controller being configured to cause the plurality of third electrodes to change from the first potential to the first potential at a fifth time after the fourth time,
the controller being configured to set the fourth electrode to a third potential at the first time,
the controller being configured to cause the fourth electrode to change from the third potential to a fourth potential higher than the third potential at a sixth time between the first time and the second time,
the controller being configured to cause the fourth electrode to change from the fourth potential to the third potential at a seventh time between the sixth time and the third time,
the controller being configured to cause the fourth electrode to change from the fourth potential to the third potential at an eighth time between the seventh time and the third time,
the controller being configured to cause the fourth electrode to change from the third potential to the fourth potential at an eighth time between the seventh time and the third time,
the controller being configured to cause the fourth electrode to change from the third potential to the fourth potential at a ninth time after the fourth time,.

15. The semiconductor device according to claim 1, further comprising:
a fifth electrode,
the fifth electrode being between one of the plurality of third electrodes and another one of the plurality of third electrodes, and
a part of the first insulating member being provided between the fifth electrode and the semiconductor member.

16. The semiconductor device according to claim 15, further comprising:
a controller,
the controller being configured to cause the plurality of third electrodes to change from a first potential to a second potential higher than the first potential at a first time,
the controller being configured to cause the plurality of third electrodes to change from the second potential to the first potential at a second time after the first time,
the controller being configured to cause the plurality of third electrodes to change from the first potential to the second potential at a third time after the second time,
the controller being configured to cause the plurality of third electrodes to change from the first potential to the second potential at a fourth time after the third time,
the controller being configured to cause the plurality of third electrodes to change from the second potential to the first potential at a fifth time after the fourth time,
the controller being configured to cause the plurality of third electrodes to change from the first potential to the second potential at a fifth time after the fourth time,
the controller being configured to set the fourth electrodes to a third potential at the first time,
the controller being configured to cause the fourth electrodes to change from the third potential to a fourth potential higher than the third potential at a sixth time between the first time and the second time,
the controller being configured to cause the fourth electrode to change from the fourth potential to the third potential at a seventh time between the sixth time and the third time,
the controller being configured to cause the fourth electrode to change from the third potential to the fourth potential at an eighth time between the seventh time and the third time,
the controller being configured to cause the fourth electrode to change from the fourth potential to the third potential at a ninth time after the fourth time,
the controller being configured to cause the fifth electrode to change from the fifth potential to a sixth potential higher than the fifth potential at the first time,
the controller being configured to cause the fifth electrode to change from the sixth potential to the fifth potential at the sixth time,
the controller being configured to cause the fifth electrode from the fifth potential to the sixth potential at the ninth time.

17. The semiconductor device according to claim 16, wherein
the controller is configured to keep the fifth electrode at the fifth potential between the sixth time and the ninth time.

18. The semiconductor device according to claim 1, wherein
the first electrode portion is provided between a part of the second electrode portion and another part of the second electrode portion in a direction crossing the first direction.

19. The semiconductor device according to claim 1, wherein
the first semiconductor portion is provided between a part of the second semiconductor portion and another part of the second semiconductor portion in a direction crossing the first direction.

20. The semiconductor device according to claim 1, wherein
a plurality of the first electrode portions are provided, and
one of the plurality of the first electrode portions is between a part of the second electrode portion and another part of the second electrode portion.
